(19) United States
(12) Patent Application Publication
(10) Pub. No.: US 2007/0007532 A1
(43) Pub. Date: Jan. 11, 2007

(54) Stacked semiconductor device and related method

(76) Inventors: Sung-Kwan Kang, Seoul (KR); Yu-Gyun Shin, Seongnam-si (KR); Jong-Wook Lee, Yongin-si (KR); Yong-Hoon Son, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/474,384

(22) Filed: Jun. 26, 2006

(30) Foreign Application Priority Data
Jul. 8, 2005 (KR) 2005-61516

(51) Int. Cl. H01L 29/10

(52) U.S. Cl. 257/67; 438/152; 257/E29.273

(57) ABSTRACT

A stacked semiconductor device and a method for manufacturing the stacked semiconductor device are disclosed. The stacked semiconductor device comprises a seed layer doped with first impurities, a multilayer insulation pattern disposed on the seed layer comprising at least two insulation interlayer patterns stacked vertically on the seed layer and an opening. The stacked semiconductor device further comprises at least one active thin layer, wherein each of the at least one active thin layers is disposed on one of the at least two insulation interlayer patterns of the multilayer insulation pattern, and wherein the opening exposes a side surface of each of the at least one active thin layers. The stacked semiconductor device still further comprises and a first plug disposed on the seed layer and doped with second impurities substantially the same as the first impurities, wherein the opening exposes a top surface of the first plug.

### BACKGROUND OF THE INVENTION

1. Field of the Invention

Embodiments of the invention relate to a semiconductor device and a method of manufacturing the semiconductor device. More particularly, embodiments of the invention relate to a stacked semiconductor device in which semiconductor structures are stacked vertically on a substrate, and a method of manufacturing the stacked semiconductor device.

This application claims priority to Korean Patent Application No. 2005-61516, filed on Jul. 8, 2005, the subject matter of which is hereby incorporated by reference in its entirety.

2. Description of the Related Art

Recently, as the design rule for semiconductor devices has decreased, there has been a tendency to require that both the size of conductive structures in semiconductor devices and the intervals between conductive structures in semiconductor devices be reduced. However, reducing the size of and intervals between the conductive structures without enlarging the size of the substrate on which the conductive structures are formed causes electrical resistance in the conductive structures to increase and reduces the electrical reliability of the semiconductor device comprising those conductive structures.

Thus, a stacked semiconductor device, in which conductive structures are stacked vertically on a substrate, has been proposed as an alternative to conventional planar layout designs. A stacked semiconductor device is disclosed for example in U.S. Pat. No. 6,538,330, the subject matter of which is hereby incorporated by reference in its entirety. Stacked semiconductor devices have been widely used in various types of devices such as static random access memory (SRAM) devices and system on chip (SOC) devices.

In a stacked semiconductor device, conductive structures are stacked vertically in a multilayer system, and an insulation interlayer pattern is formed on each level of conductive structures. When an upper level of conductive structures is formed above a lower level of conductive structures, the upper level of conductive structures requires an active thin layer to use as a channel region. In general, an active thin layer is formed on a substrate through a selective epitaxial growth (SEG) process using a substrate exposed through an opening in a corresponding insulation interlayer pattern as a seed. As the active thin layer is formed, a contact plug is simultaneously formed in the opening.

Further, the conductive structures stacked vertically in the multilayer system need to be electrically connected with each other. Each insulation interlayer in the multilayer system is patterned to thereby form an opening through which the substrate is partially exposed and through which each insulation interlayer may be connected with one another. The opening in each insulation interlayer is filled with a conductive material such as metal to thereby form a metal wiring through which the conductive structures are electrically connected with each other. The stacked semiconductor device requires that the opening expose a portion of the surface of the substrate and a sidewall of the active thin layer of each insulation interlayer comprising an active thin layer.

However, the creation of the opening in the insulation interlayers may create various defects in the stacked semiconductor device. As shown in FIG. 1, when the opening is not etched deeply enough through the insulation interlayers, the opening exposes a plug that does not comprise impurities rather than a surface of the substrate. Because the plug does not comprise impurities, the metal wiring subsequently formed in the opening will have an undesirably high electrical resistance. Alternatively, as shown in FIG. 2, when the opening is etched through the insulation interlayers too deeply, the opening exposes a portion of the substrate that is below the surface of the substrate. When the opening is etched too deeply, as described previously, current may leak from the metal wiring formed in the opening.

In particular, when the opening is formed in the insulation interlayers through an etching process in the conventional stacked semiconductor device, a preset ending time for the etching process determines how deeply the insulation interlayers are etched. Thus, it is difficult to form an opening that exposes the surface of the substrate (i.e., an opening etched exactly to the surface of the substrate) in the conventional stacked semiconductor device, so the electrical reliability of the conventional stacked semiconductor device may be impaired.

### SUMMARY OF THE INVENTION

Accordingly, the present invention provides a stacked semiconductor device comprising a plug adapted to readily indicate an ending point for an etching process, and a method for manufacturing the stacked semiconductor device.

In one embodiment, the invention provides a stacked semiconductor device comprising a seed layer doped with first impurities, and a multilayer insulation pattern disposed on the seed layer comprising at least two insulation interlayer patterns stacked vertically on the seed layer and an opening. The stacked semiconductor device further comprises at least one active thin layer, wherein each of the at least one active thin layers is disposed on one of the at least two insulation interlayer patterns of the multilayer insulation pattern, and wherein the opening exposes a side surface of each of the at least one active thin layers. The stacked semiconductor device further comprises a first plug disposed on the seed layer and doped with second impurities substantially the same as the first impurities, wherein the opening exposes at least a portion of a top surface of the first plug.

In another embodiment, the invention provides a method of manufacturing a stacked semiconductor device comprising doping a seed layer with first impurities, forming a multilayer insulation pattern on the seed layer, wherein the multilayer insulation pattern comprises at least two insulation interlayer patterns vertically stacked on the seed layer and an opening, forming at least one active thin layer, wherein each of the at least one active thin layers is formed on one of the at least two insulation interlayer patterns of the multilayer insulation pattern, and wherein the opening exposes a side surface of each of the at least one active thin layers. The method further comprises forming a first plug doped with second impurities substantially the same as the first impurities on the seed layer, wherein forming the first plug on the seed layer comprises growing a base layer by performing a first selective epitaxial growth (SEG) process using the seed layer as a seed and doping the base layer with second impurities, and forming a metal wiring in the opening, wherein the metal wiring is electrically connected to the first plug.

In yet another embodiment, the invention provides a method of manufacturing a stacked semiconductor device comprising forming a first semiconductor structure on a semiconductor substrate, wherein the first semiconductor structure comprises a first gate pattern and first source/drain regions doped with first impurities; forming a first insulation interlayer on the semiconductor substrate after forming the first semiconductor structure; and, patterning the first insulation interlayer to form a first insulation interlayer pattern comprising a first opening, wherein the first opening exposes a portion of the semiconductor substrate comprising at least a portion of a first source/drain region of the first semiconductor structure. The method further comprises forming a first plug doped with first plug impurities in the first opening and on the portion of the semiconductor substrate exposed by the first opening, wherein forming the first plug comprises forming a base layer through a first selective epitaxial growth (SEG) process using the portion of the semiconductor substrate exposed through the first opening as a seed and doping the base layer with first plug impurities substantially the same as the first impurities. The method still further comprises forming a second plug not doped with impurities on the first plug in the first opening after forming the first plug; forming a first active thin layer on the first insulation interlayer pattern after forming the second plug; forming a second semiconductor structure on the first active thin layer, wherein the second semiconductor structure comprises a second gate pattern and second source/drain regions doped with second impurities; and, forming a second insulation interlayer on the first active thin layer after forming the second semiconductor structure on the first active thin layer. The method still further comprises forming a second opening, wherein forming the second opening comprises etching the first active thin layer and the second plug using the first plug in the first opening as an etching stop layer, and wherein the second opening exposes a side surface of the first active thin layer comprising a side surface of at least one second source/drain region and a top surface of the first plug; and, forming a metal wiring in the second opening, wherein the metal wiring is electrically connected to the first plug in the first opening.

### BRIEF DESCRIPTION OF THE DRAWINGS

Exemplary embodiments of the invention will be described herein with reference to the accompanying drawings, in which like reference symbols refer to like or similar elements throughout.

FIGS. 1 and 2 are photographs showing a conventional stacked semiconductor device;

FIG. 3 is a cross-sectional view illustrating a double-stacked semiconductor device in accordance with an exemplary embodiment of the present invention;

FIG. 4 is a cross-sectional view illustrating a double-stacked semiconductor device in accordance with another exemplary embodiment of the present invention;

FIGS. 5A through 5I are cross-sectional views illustrating a method for manufacturing the double-stacked semiconductor device shown in FIG. 3;

FIG. 6 is a cross-sectional view illustrating a triple-stacked semiconductor device in accordance with an exemplary embodiment of the present invention;

FIG. 7 is a cross-sectional view illustrating a triple-stacked semiconductor device in accordance with another exemplary embodiment of the present invention; and,

FIGS. 8A through 8F are cross-sectional views illustrating a method for manufacturing the triple-stacked semiconductor device shown in FIG. 6.

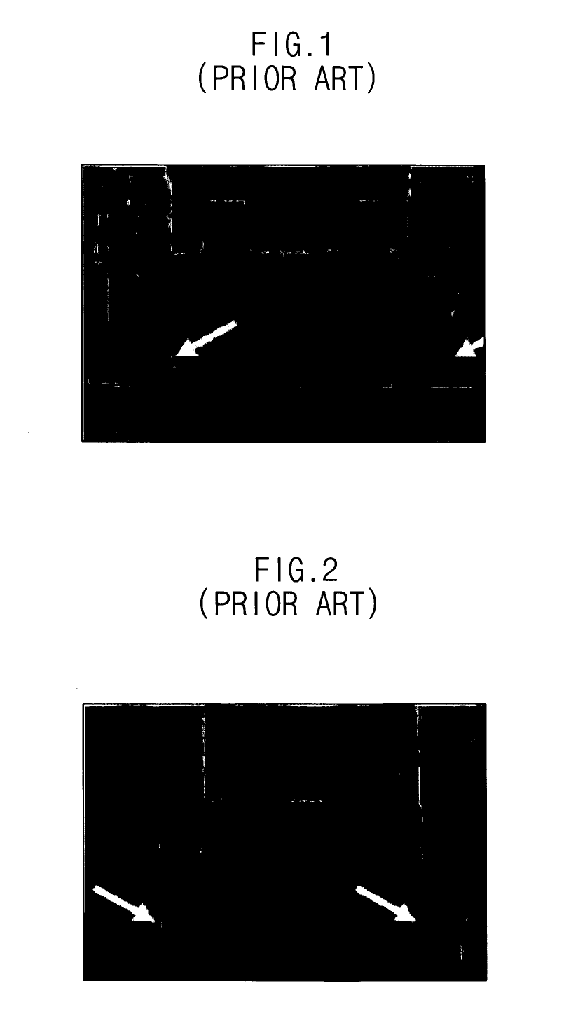

### DESCRIPTION OF THE EXEMPLARY EMBODIMENTS

In the drawings, the size and relative sizes of layers and regions may be exaggerated for clarity.

It will be understood that when an element or layer is referred to as being “on,” “connected to,” or “coupled to” another element or layer, it can be directly on, connected, or coupled to the other element or layer or intervening elements or layers may be present. In contrast, when an element is referred to as being “directly on,” “directly connected to,” or “directly coupled to” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers, and/or sections, these elements, components, regions, layers, and/or sections are not limited by these terms. These terms are only used to distinguish one element, component, region, layer, or section from another element, component, region, layer, or section. Thus, a first element, component, region, layer, or section discussed below could be referred to as a second element, component, region, layer, or section without departing the scope of the present invention.

Spatially relative terms, such as “beneath,” “below,” “lower,” “above,” “upper,” etc., may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if a device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments of the invention are described herein with reference to cross-sectional illustrations that are schematic illustrations of idealized embodiments (and intermediate structures) of the invention. As such, variations from the shapes of the illustrations as a result of, for example, manufacturing techniques and/or tolerances, are to be expected. Thus, embodiments of the invention should not be construed as limited to the specific shape of the various regions illustrated herein, but also encompass other shapes that may result from variances in manufacturing processes. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to limit the scope of the invention.

Double-Stacked Semiconductor Device and Related Manufacturing Method

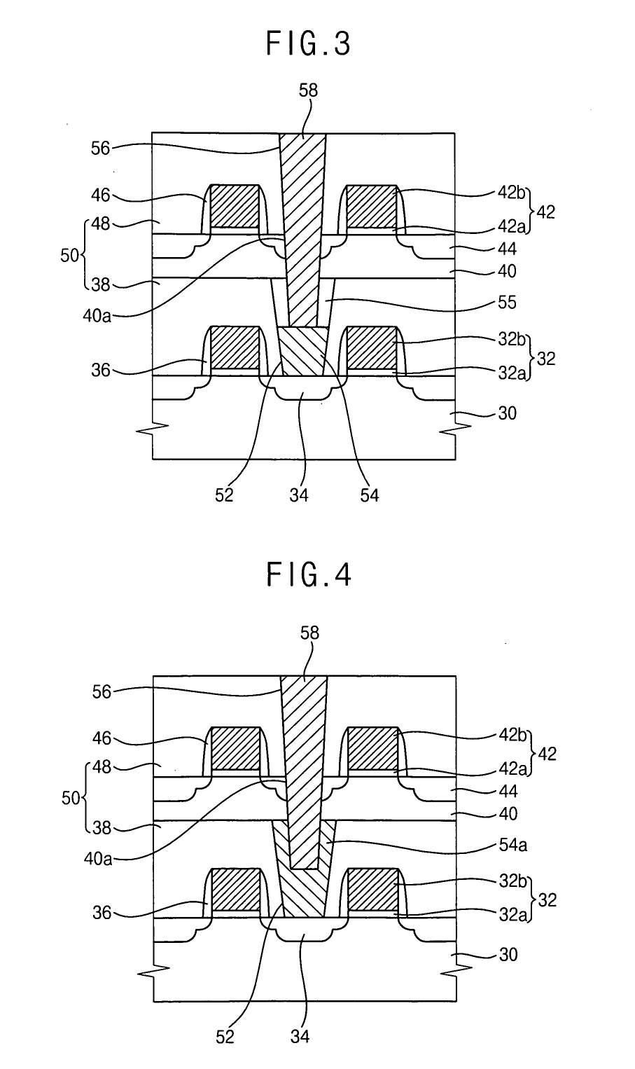

FIG. 3 is a cross-sectional view illustrating a double-stacked semiconductor device in accordance with an exemplary embodiment of the present invention. The double-stacked semiconductor device of FIG. 3 comprises a seed layer 30 disposed at a bottom portion of the double-stacked semiconductor device. Seed layer 30 may be a silicon substrate, silicon-on-insulation (SOI) substrate, a germanium substrate, a germanium-on-insulation (GOI) substrate, a silicon-germanium substrate, or an epitaxial layer formed by a selective epitaxial growth (SEG) process. In the illustrated embodiment, seed layer 30 is a semiconductor substrate, such as a silicon substrate or a germanium substrate, because seed layer 30 is disposed at the bottom portion of the double-stacked semiconductor device.

Though first and second semiconductor structures of the double-stacked semiconductor device of FIG. 3 each comprise a plurality of transistors, the first and second semiconductor structures will each primarily be described herein with reference to respective examples.

A first gate pattern 32 is formed on seed layer 30 and first source/drain regions 34 doped with first impurities are formed in surface portions of seed layer 30 adjacent to first gate pattern 32. As a result, a first semiconductor structure comprising a transistor comprising first gate pattern 32, which comprises a first gate insulation pattern 32a and a first gate conductive pattern 32b, and first source/drain regions 34 is formed on seed layer 30. Boron (B), phosphorus (P), arsenic (As), etc., are examples of first impurities. In the illustrated embodiment, the previously mentioned exemplary first impurities may each be used individually. A first spacer 36 is also formed on a first sidewall of first gate pattern 32. Through a sequential ion implantation process performed using first gate pattern 32 as an ion implantation mask and using first gate pattern 32 in combination with first spacer 36 as an ion implantation mask, a lightly-doped junction area and a heavily-doped junction area are formed in source/drain regions 34, which are conventionally known as a lightly doped source/drain (LDD) structures.

When the first semiconductor structure comprises an NMOS (i.e., N-type MOS) transistor, the first impurities comprise at least phosphorus (P) or arsenic (As), and when the first semiconductor structure comprises a PMOS (i.e., P-type MOS) transistor, the first impurities comprise boron (B). Additionally, the first semiconductor device of the exemplary embodiment illustrated in FIG. 3 may further comprise a logic device and/or metal wiring in accordance with a circuit design, as would be known to one of ordinary skill in the art.

A multilayer insulation pattern 50 comprising a first insulation interlayer pattern 38 and a second insulation interlayer pattern 48 is also formed on seed layer 30. First and second insulation interlayer patterns 38 and 48 are stacked vertically on seed layer 30. That is, first insulation interlayer pattern 38 is formed on seed layer 30 and second insulation interlayer pattern 48 is formed on first insulation interlayer pattern 38. Because the embodiment illustrated in FIG. 3 is a double-stacked semiconductor device, multilayer insulation pattern 50 comprises two insulation interlayer patterns, i.e., first and second insulation interlayer patterns 38 and 48. When the stacked semiconductor device of the present invention is a triple-stacked semiconductor device, as in another exemplary embodiment that will be described subsequently, the multilayer insulation pattern (i.e., a multilayer insulation pattern 80) comprises three insulation interlayer patterns.

In addition, a first active thin layer 40 is formed on first insulation interlayer pattern 38. First active thin layer 40 may be formed by, for example, forming an epitaxial layer on first insulation interlayer 38 by a selective epitaxial growth (SEG) process and patterning the epitaxial layer through a photolithography process.

A second semiconductor structure substantially the same as the first semiconductor structure is formed on first active thin layer 40. The second semiconductor structure comprises a second gate pattern 42, comprising a second insulation pattern 42a and a second gate conductive pattern 42b, and second source/drain regions 44 doped with second impurities. A second spacer 46 is formed on a first sidewall of second gate pattern 42, and second source/drain regions 44 also comprise an LDD structure formed through substantially the same process as the process for forming the LDD structure of first source/drain regions 34 of the first semiconductor structure.

The second semiconductor structure may further comprise a logic device and metal wiring in accordance with a circuit design, as would be known to one of ordinary skill in the art.

Like the first semiconductor structure, when the second semiconductor structure comprises an NMOS transistor, the second impurities comprise phosphorus (P) or arsenic (As), and when the second semiconductor structure comprises a PMOS transistor, the second impurities comprise boron (B). First insulation interlayer pattern 38 comprises a first opening 52 that exposes a first portion of a top surface of seed layer 30. As used herein, an opening in a pattern “exposes” an element or region when the opening borders directly on the element or region, whether the opening is subsequently filled or not. In particular, first opening 52 exposes a portion of a selected first source/drain region 34 formed in seed layer 30 of the first semiconductor structure. Additionally, a first plug 54 doped with first plug impurities is formed on the portion of the selected first source/drain region 34 that first opening 52 exposes.

In the illustrated embodiment, first plug 54 is formed through an SEG process and is doped with first plug impurities substantially the same as the first impurities. Accordingly, when, for example, first source/drain regions 34 are doped with boron (B) as the first impurities, first plug 54 is doped with boron (B) as the first plug impurities, and when, as another example, first source/drain regions 34 are doped with phosphorus (P) as the first impurities, first plug 54 is doped with phosphorus (P) as the first plug impurities.

Further, multilayer insulation pattern 50 comprises a second opening 56 disposed over the first portion of the top surface of seed layer 30. Second opening 56 penetrates through first and second insulation interlayer patterns 38 and 48 and is connected to first opening 52. In the illustrated embodiment, first plug 54 is formed on seed layer 30 in first opening 52 such that second opening 56 exposes a top surface of first plug 54. Because second opening 56 penetrates though first and second insulation interlayer patterns 38 and 48, second opening 56 exposes a sidewall 40a of first active thin layer 40 in addition to first plug 54. In particular, sidewall 40a of first active thin layer 40 comprises a sidewall of at least one second source/drain region 44 of the second semiconductor structure.

Second opening 56 is filled with a metal wiring 58 that makes contact with first plug 54. In the illustrated embodiment, metal wiring 58 comprises a barrier wiring formed continuously along a sidewall and a bottom portion of second opening 56 and a filling wiring that fills second opening 56. The barrier wiring may comprise titanium, titanium nitride, or a combination thereof, and the filling wiring may comprise aluminum, tungsten, copper, or a combination thereof. For example, the barrier wiring may comprise a multilayer structure comprising a titanium layer and a titanium nitride layer formed on the titanium layer.

Metal wiring 58 disposed in second opening 56 makes electrical contact with first plug 54 in first opening 52. Since first plug 54 is doped with the first plug impurities, first plug 54 has a relatively low electrical resistance.

In the illustrated embodiment, first plug 54 fills a lower portion of first opening 52 and a second plug 55, which is not doped with impurities, fills an upper portion of first opening 52.

When, in another exemplary embodiment, first plug 54 completely fills first opening 52, first active thin layer 40, in addition to first plug 54, is doped with first plug impurities. That is, in the exemplary process for forming a double-stacked semiconductor device in which first plug 54 completely fills first opening 52, an epitaxial layer that will be formed into thin layer 40 in a subsequent process is doped with first plug impurities in addition to first plug 54. So, for example, when first plug 54 is doped with boron (B) as the first plug impurities, first active thin layer 40 is also doped with boron (B), and, as a result, only a PMOS transistor may be formed on first active thin layer 40 as the second semiconductor structure. That is, an NMOS transistor may not be formed on first active thin layer 40 because first active thin layer 40 has already been doped with boron (B).

For that reason, in the illustrated embodiment (i.e., in the embodiment illustrated in FIG. 3), first plug 54 fills the lower portion of first opening 52 and second plug 55, which is not doped with impurities, fills the upper portion of first opening 52. An SEG process is performed on second plug 55, and an epitaxial layer is grown from second plug 55. The epitaxial layer will be formed into first active thin layer 40 in a subsequent process. Accordingly, first active thin layer 40 is not doped with impurities because the epitaxial layer from which it was formed was not doped along with first plug 54, so the type of transistor (i.e., PMOS or NMOS) that the second semiconductor structure may comprise is not limited.

Furthermore, when, as in the illustrated embodiment, first and second plugs 54 and 55 fill first opening 52, first plug 54 is used as an etching stop layer in an etching process for forming second opening 56 so that second opening 56 is correctly formed at a top portion of first plug 54.

When the double-stacked semiconductor device of FIG. 3 is manufactured to be a double-stacked static random access memory (SRAM), the first semiconductor structure comprises a plurality of NMOS transistors formed on seed layer 30, and the second semiconductor structure comprises a plurality of PMOS transistors formed on first active thin layer 40. The first semiconductor structure is adapted to function as a pair of pull-down devices and a pair of access devices and the second semiconductor structure is adapted to function as a pair of pull-up devices. The NMOS transistors and the PMOS transistors are electrically connected with each other through first plug 54 and metal wiring 58, thereby forming a double-stacked SRAM device having a sufficiently reduced electrical resistance relative to a conventional stacked semiconductor device.

Although first and second plugs 54 and 55 fill first opening 52 in the embodiment illustrated in FIG. 3, in another exemplary embodiment, first opening 52 may be filled by an alternate first plug 54a alone, as illustrated in FIG. 4. However, the embodiment illustrated in FIG. 4 is troublesome because the epitaxial layer formed on first insulation interlayer 38 and doped with the first impurities when alternate first plug 54a is formed through an SEG process needs to be removed.

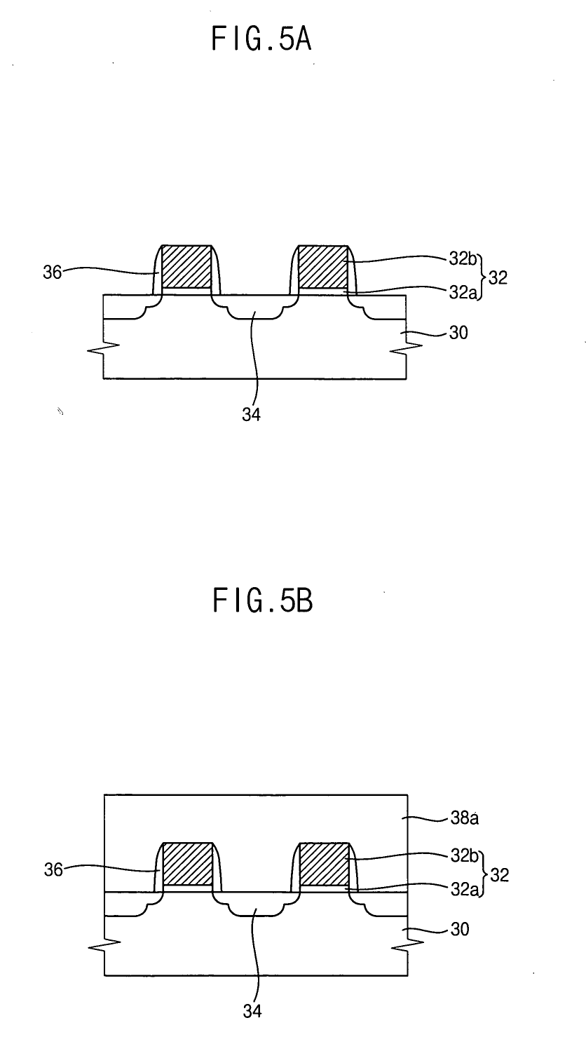

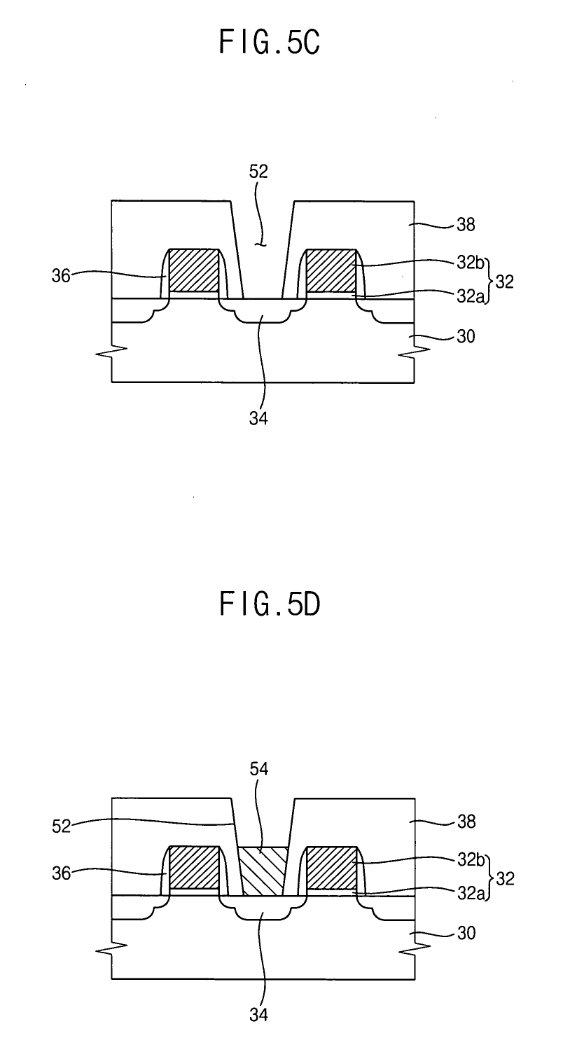

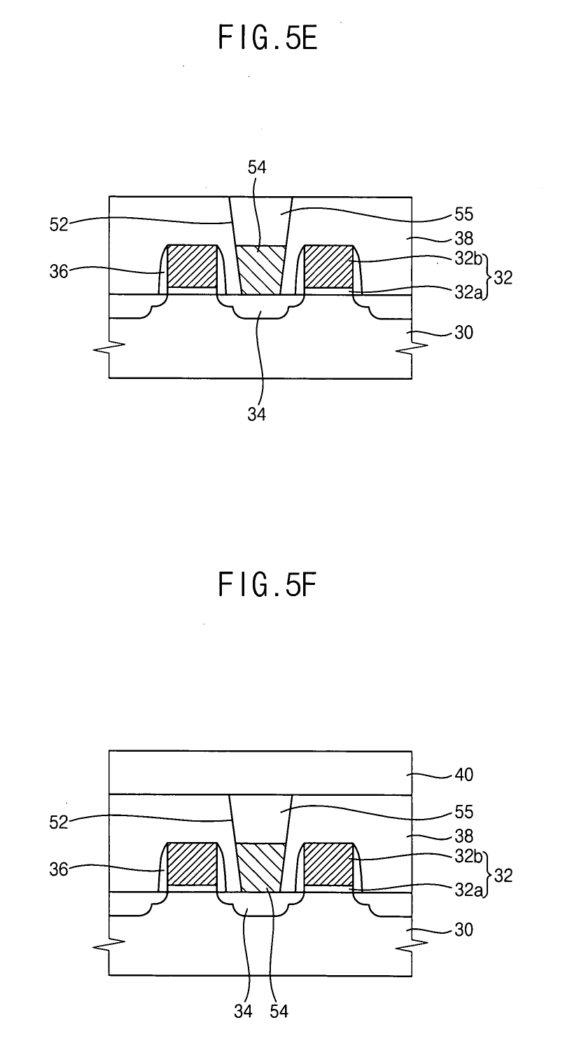

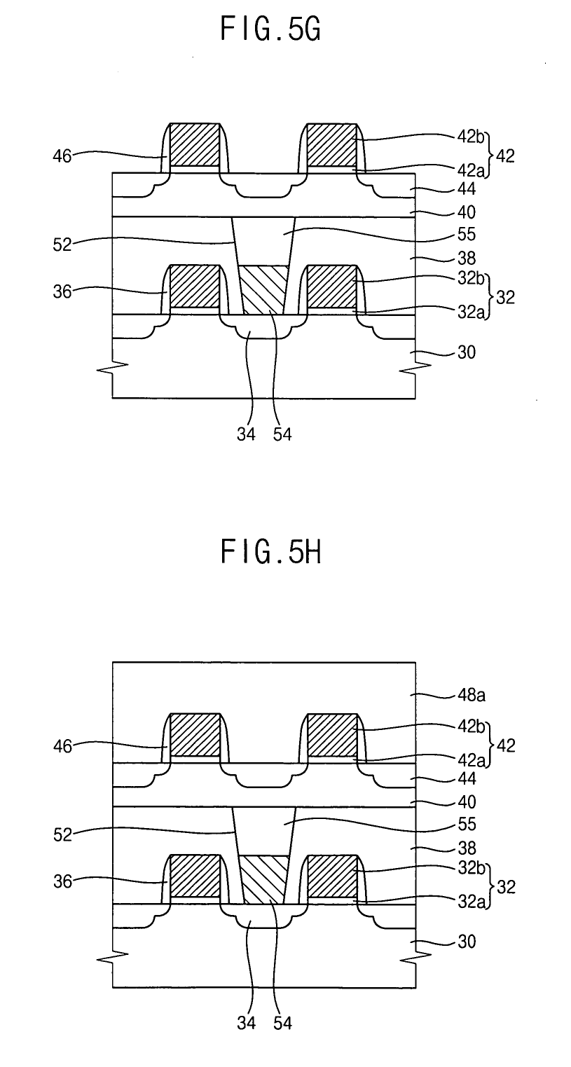

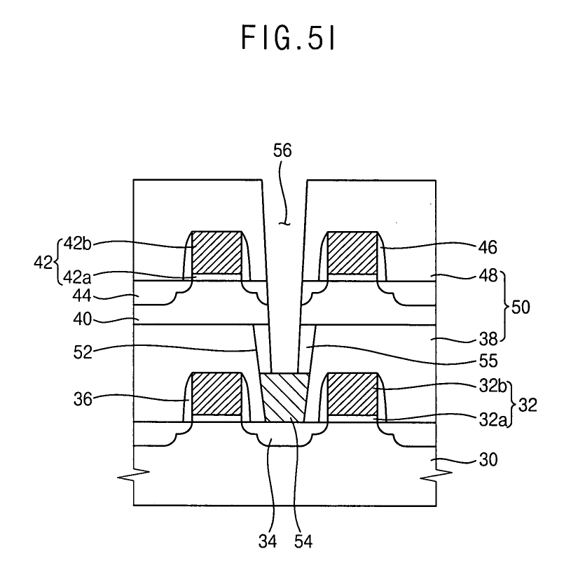

Hereinafter, a method of manufacturing the double-stacked semiconductor device of FIG. 3 will be described with reference to FIGS. 5A through 5I.

FIGS. 5A through 5I are cross-sectional views illustrating a method for manufacturing the double-stacked semiconductor device shown in FIG. 3.

Referring to FIG. 5A, a seed layer 30 is prepared to receive the double-stacked semiconductor device illustrated in FIG. 3. As described above, seed layer 30 may be formed from a silicon substrate, a silicon-on-insulation (SOI) substrate, a germanium substrate, a germanium-on-insulation (GOI) substrate, a silicon-germanium substrate, or an epitaxial layer formed through a selective epitaxial growth (SEG) process. In the embodiment illustrated in FIG. 5, a semiconductor substrate, such as a silicon substrate or a germanium substrate, is used as seed layer 30 because seed layer 30 is disposed at the bottom portion of the semiconductor device. For that reason, seed layer 30 is often referred to as a semiconductor substrate.

A trench device isolation layer (not shown) is formed in seed layer 30, thereby defining an active region and a field region. The trench device isolation layer is formed to increase the degree of integration of semiconductor devices formed on seed layer 30.

A process for forming the trench device isolation layer in seed layer 30 will now be described. A pad oxide layer and a pad nitride layer are sequentially formed on seed layer 30 and are patterned through a photolithography process, thereby forming a pad oxide pattern and a pad nitride pattern through which a surface of seed layer 30 is partially exposed. An etching process is then performed on seed layer 30 using the pad oxide pattern and the pad nitride pattern as an etching mask, thereby forming trenches in seed layer 30. A curing process may be further performed on seed layer 30 to cure any damage to seed layer 30 caused by formation of the trench device isolation layer. An oxide thin layer is then formed on the resultant structure comprising the trenches to a thickness sufficient to fill the trenches through a plasma-enhanced chemical vapor deposition (PECVD) process. Then, the oxide thin layer is partially removed and planarized through a chemical mechanical polishing (CMP) process until a top surface of the pad nitride pattern is exposed. The pad nitride pattern and the pad oxide pattern are then removed from seed layer 30 through a wet etching process using a phosphoric acid solution as an etchant. Accordingly, the thin oxide layer remains only in the trenches formed in seed layer 30, thereby forming a trench device isolation layer in seed layer 30.

Again, though the first and second semiconductor structures of the double-stacked semiconductor device formed through the method illustrated in FIG. 5 each comprise a plurality of transistors, the first and second semiconductor structures will each primarily be described herein with reference to exemplary transistors.

A first gate pattern 32, which comprises a first gate insulation pattern 32a and a first gate conductive pattern 32b, and first source/drain regions 34 are formed on an active region of seed layer 30.

Particularly, an insulation layer (not shown) and a conductive layer (not shown) are formed on seed layer 30. The insulation layer comprises oxide or metal oxide, and the conductive layer comprises polysilicon; metal, or metal nitride.

In the illustrated embodiment (i.e., the embodiment illustrated in FIG. 5), the insulation layer comprises metal oxide having a sufficient equivalent oxide thickness (EOT) and superior current leakage characteristics to increase the degree of integration of semiconductor devices formed on seed layer 30. To form the insulation layer, a metal oxide layer is formed on seed layer 30 through, for example, an atomic layer deposition (ALD) process. To form the conductive layer, a metal nitride layer is formed on the metal oxide layer through a chemical vapor deposition (CVD) process.

In the illustrated embodiment, the ALD process for forming the metal oxide layer as the insulation layer comprises the following sequential steps: a first providing step for providing source material, a first purging step for removing residual source material, a second providing step for providing an oxidizing agent, and a second purging step for removing a residual oxidizing agent. A cycle of the ALD process is performed by sequentially performing the above steps, and the thickness of the insulation layer produced through the ALD process corresponds to the number of cycles of the ALD process that are performed in forming the insulation layer. In the illustrated embodiment, at least one cycle of the ALD process is performed, and the insulation layer of metal oxide is thereby formed on seed layer 30. The source material mentioned above comprises a metal precursor. The source material may comprise, for example, tetrakis ethyl methyl amino hafnium (TEMAH, Hf[NC₂H₅CH₃]₄) or hafnium butyl oxide (Hf(O-tBu)₄) when a hafnium precursor is used in the ALD process, and may comprise, for example, trimethyl aluminum (TMA, AL(CH₃)₃) when an aluminum precursor is used in the ALD process. The oxidizing agent may be, for example, ozone (O₃), water vapor (H₂O), non-activated oxygen (O₂), oxygen (O₂) activated by plasma or remote plasma, etc. These exemplary oxidizing agents can be used alone or in combinations thereof.

Further, titanium nitride is deposited onto the insulation layer through a CVD process at a temperature of no more than about 550° C. using a source gas comprising, for example, titanium chloride (TiCl4) gas and ammonium (NH3) gas, thereby forming on the insulation layer a metal nitride layer as the conductive layer.

Then, the insulation layer and the conductive layer are patterned through a photolithography process to thereby form first gate pattern 32. In more detail, a photoresist pattern (not shown) is formed on the conductive layer, and the conductive and insulation layers are partially removed through an etching process using the photoresist pattern as an etching mask, thereby forming first gate conductive pattern 32b and first gate insulation pattern 32a under first gate conductive pattern 32b. Thereafter, the photoresist pattern is removed from first gate conductive pattern 32b. Accordingly, first gate pattern 32 comprising first gate conductive pattern 32b and first gate insulation pattern 32a is formed on seed layer 30.

Although first gate conductive pattern 32b comprises metal nitride in the illustrated embodiment described above, first gate conductive pattern 32b may also comprise a multilayer structure comprising a polysilicon layer, a metal layer, a metal nitride layer, and/or a metal silicide layer.

To form a lightly-doped junction area doped with first impurities at surface portions of seed layer 30 adjacent to first gate pattern 32, an ion implantation process is performed on seed layer 30 using first gate pattern 32 as an implantation mask. In the illustrated embodiment, the first impurities doped into the lightly-doped junction area comprise at least one of boron (B), phosphorus (P), or arsenic (As). When the double-stacked semiconductor device is manufactured to be a double-stacked SRAM, phosphorus (P) or arsenic (As) may be implanted into seed layer 30 as first impurities because NMOS transistors are formed on seed layer 30 in a double-stacked SRAM.

A first spacer 36 comprising silicon nitride is formed on a first sidewall of first gate pattern 32 through an etching process having a defined etching selectivity. In more detail, after first gate pattern 32 is formed on seed layer 30, a silicon nitride layer (not shown) is formed on seed layer 30 and is then etched using an etch process having a defined etching selectively with respect to first gate insulation pattern 32a until portions of a top surface of seed layer 30 are exposed. A portion of the silicon nitride layer then remains on the first sidewall of first gate pattern 32, thereby forming first spacer 36 on the first sidewall of first gate pattern 32.

An ion implantation is again performed at surface portions of seed layer 30 using first gate pattern 32 and first spacer 36 as an implantation mask, so that a heavily-doped junction area is formed at surface portions of seed layer 30 adjacent to first spacer 36. The ions implanted to form the heavily-doped junction area may comprise the same ions as the first impurities in the lightly-doped junction area; however, the concentration of ions in the heavily-doped junction area is higher than that of the lightly-doped junction area.

Alternatively, first spacer 36 may not be formed on a sidewall of first gate pattern 32. When no spacer 36 is formed on a sidewall of first gate pattern 32, the lightly-doped junction area (i.e., the shallow junction area) becomes a first source/drain region 34 after the ions are implanted to form the heavily-doped junction area.

Accordingly, the lightly-doped junction area and the heavily-doped junction area are formed at surface portions of seed layer 30 adjacent to first gate pattern 32 and first spacer 36, thereby forming first source/drain regions 34 at surface portions of seed layer 30. As a result, a first semiconductor structure comprising first gate pattern 32 and first source/drain regions 34 is formed on seed layer 30.

Referring to FIG. 5B, after the first semiconductor structure is formed on seed layer 30, a first insulation interlayer 38a is formed on seed layer 30. In the illustrated embodiment, first insulation interlayer 38a comprises a silicon oxide layer. A borophosphor silicate glass (BPSG) layer, a phosphor silicate glass (PSG) layer, an undoped silicate glass (USG) layer, and a spin on glass (SOG) layer are each exemplary silicon oxide layers.

Referring to FIGS. 5B and 5C, first insulation interlayer 38a is patterned through a photolithography process to form first insulation interlayer pattern 38 comprising first opening 52 which partially exposes seed layer 30. In the illustrated embodiment, first opening 52 exposes at least a portion of first source/drain region 34 formed in seed layer 30 because first source/drain region 34 needs to be electrically connected to (e.g.), a contact pad, wiring layer, or plug.

To form first opening 52, a photoresist pattern (not shown) is formed on first insulation interlayer 38a, and a region of first insulation interlayer 38a corresponding to a selected first source/drain region 34 of seed layer 30 is at least partially exposed through the photoresist pattern. Then, first insulation interlayer 38a is partially removed through an etching process using the photoresist pattern as an etching mask, thereby forming first insulation interlayer pattern 38 through which at least a portion of the selected first source/drain region 34 of seed layer 30 is exposed. The photoresist pattern is then removed from first insulation interlayer pattern 38 through an ashing process or a stripping process.

Referring to FIG. 5D, a first plug 54 is formed in first opening 52 and is doped with first plug impurities substantially identical to the first impurities implanted into source/drain regions 34.

First plug 54 is formed through performing an SEG process and a doping process for doping first plug 54 with first plug impurities. The first plug impurities are substantially the same as the first impurities of first source/drain regions 34. For example, when phosphorus (P) is doped into seed layer 30 as the first impurities, first plug 54 is doped with phosphorus (P) as the first plug impurities. Phosphorus (P), boron (B), and arsenic (As) are exemplary first plug impurities.

Through the SEG process, a base layer, from which first plug 54 is formed, is grown from the portion of the surface of seed layer 30 that first opening 52 exposes. When the SEG process is performed at a temperature of less than about 600° C., it is difficult to grow the base layer, and when the SEG process is performed at a temperature of more than about 1,100° C., thermal stress is applied to the first semiconductor structure. Accordingly, the SEG process is performed at a temperature of about 600° C. to 1,100° C., and, in the illustrated embodiment, is performed at a temperature of about 600° C. to 900° C.

First plug impurities are doped into first plug 54 through a gas flow or an ion implantation process. In the gas flow process, the gas comprising the first plug impurities is supplied to a process chamber containing a semiconductor wafer comprising seed layer 30 or an intermediate structure formed on seed layer 30, at the same time as the SEG process is performed on seed layer 30, and the first plug impurities are doped into the base layer while the SEG process is performed on the portion of seed layer 30 that first opening 52 exposes. Accordingly, the first plug doped with first plug impurities is thereby formed through the SEG and doping processes.

When first plug 54 is doped with first plug impurities through a gas flow process, diborane (B₂H₆) or boron chloride (BCl₃) may be used as a gas source comprising boron (B); and phosphorus chloride (PCl₄), phosphorus oxychloride (POCl₃), or phosphine (PH₃) may be used as a gas source comprising phosphorus (P). Additionally, arsine (AsH₃) may be used as a gas source comprising arsenic gas. Alternatively, when first plug 54 is doped with first plug impurities through an ion implantation process, 11B+ or 49BF2+ may be used as a boron ion source, and 31P+ may be used as a phosphorus ion source. Additionally, 75As+ may be used as an arsenic ion source for the ion implantation process mentioned above.

In the illustrated embodiment, first plug 54 is formed at a lower portion of first opening 52 and is doped with first plug impurities at a rate of about 1E18 ions/cm3 to 4E18 ions/cm3. As a result, first plug 54 is formed in first opening 52 through performing an SEG process and a doping process through which first plug 54 is doped with first plug impurities substantially identical to the first impurities of first source/drain regions 34. In the illustrated embodiment, first plug 54 is formed at a lower portion of first opening 52.

Referring to FIG. 5E, a second plug 55 is formed on first plug 54. Second plug 55 fills an upper portion of first opening 52, and first and second plugs 54 and 55 completely fill first opening 52. In the illustrated embodiment, second plug 55 is formed through an SEG process under pressure conditions ensuring that no impurities are implanted into second plug 55.

When first plug 54 is doped with first plug impurities through a gas flow process performed at the same time as the SEG process is performed, merely stopping the gas flow and continuing the SEG process is a sufficient method for forming second plug 55 such that second plug 55 is not doped with any impurities. That is, the SEG process through which first plug 54 is performed is continued without the gas flow, and second plug 55 is thereby formed on first plug 54 without being doped with any impurities. Alternatively, when first plug impurities are doped into first plug 54 through an ion implantation process performed after the SEG process is performed, second plug 55 is formed on first plug 54 by repeating the SEG process after performing the ion implantation process on first plug 54 and then not performing an ion implantation process on second plug 55. As a result, second plug 55 is formed on first plug 54 without any impurities implanted in second plug 55.

Additionally, first opening 52 is filled through the processes described above for forming first and second plugs 54 and 55.

In addition, when the SEG process continues after second plug 55 has been formed and an epitaxial lateral overgrowth (ELO) process is performed on a surface of first insulation interlayer pattern 38, an epitaxial thin layer, which may subsequently be used to form first active thin layer 40, may be formed on first insulation interlayer pattern 38.

However, in the illustrated embodiment, the ELO process is not performed in the SEG process through which second plug 55 is formed, and second plug 55 fills up the upper portion of first opening 52. That is, first and second plugs 54 and 55 completely fill first opening 52.

Referring to FIG. 5F, a first active thin layer 40 is formed on first insulation interlayer pattern 38 and second plug 55. First active thin layer 40 is formed as a channel region for a semiconductor structure and has a structure substantially the same as that of seed layer 30.

To form a first active thin layer 40, an amorphous silicon layer (not shown) is formed on first insulation interlayer pattern 38 and second plug 55 and a heat treatment is performed on the amorphous silicon layer to transform the amorphous silicon layer into a single crystalline epitaxial layer (not shown). In an exemplary heat treatment, a laser is irradiated onto the amorphous silicon layer for a few seconds to a few hundred seconds to provide heat sufficient to transform the amorphous silicon layer. It is difficult to form a device isolation layer in active thin layer 40, so a patterning process such as a photolithography process is performed on the epitaxial layer to thereby form first active thin layer 40.

Referring to FIG. 5G, a second semiconductor structure comprising a second gate pattern 42 and second source/drain regions 44 is formed on first active thin layer 40. The second semiconductor structure is formed through substantially the same process as the process through which the first semiconductor structure is formed.

An insulation layer and a conductive layer are formed on first active thin layer 40 through substantially the same process as the process for forming the insulation layer and the conductive layer described with reference to FIG. 5A. The insulation and conductive layers are then patterned through a photolithography process. Accordingly, second gate pattern 42 comprising second gate insulation pattern 42a and second gate conductive pattern 42b is formed on first active thin layer 40. An ion implantation process is then performed at surface portions of first active thin layer 40 using second gate pattern 42 as an implantation mask to thereby form a lightly-doped junction area adjacent to second gate pattern 42. A second spacer 46 is then formed on the first sidewall of second gate pattern 42, and an ion implantation process is repeated at surface portions of first active thin layer 40 using second gate pattern 42 and second spacer 46 as an implantation mask, thereby forming a heavily-doped junction area adjacent to second spacer 46. Accordingly, lightly-doped source/drain (LLD) structures each comprising a lightly-doped junction area and a heavily-doped junction area are formed at surface portions of first active thin layer 40 as source/drain regions 44.

The impurities in second source/drain regions 44 of the second semiconductor structure may be different from the first impurities in first source/drain regions 34 of the first semiconductor structure, so the impurities in second source/drain regions 44 will be referred to hereinafter as second impurities.

Referring to FIG. 5H, a second insulation interlayer 48a is formed on first active thin layer 40 comprising the second semiconductor structure. Second insulation interlayer 48a comprises the same structure as first insulation interlayer 38a, so second insulation interlayer 48a comprises a silicon oxide layer. A borophosphor silicate glass (BPSG) layer, a phosphor silicate glass (PSG) layer, an undoped silicate glass (USG) layer, and a spin on glass (SOG) layer are each exemplary silicon oxide layers.

Referring to FIGS. 5H and 5I, second insulation interlayer 48a is partially etched to form a second insulation interlayer pattern 48 on first active thin layer 40. In addition to second insulation interlayer 48a, first active thin layer 40 and second plug 55 disposed at the upper portion of first opening 52 are continuously and partially etched to thereby form a second opening 56 that penetrates second insulation interlayer pattern 48, active thin layer 40, and second plug 55 disposed in first opening 52 of insulation interlayer pattern 38. Accordingly, a multilayer insulation pattern 50 comprising first insulation interlayer pattern 38 and second insulation interlayer pattern 48 is formed on seed layer 30, and second opening 56 is formed in multilayer insulation pattern 50. In addition, second opening 56 is formed over the selected first source/drain region 34 of the first semiconductor structure. In the illustrated embodiment, first plug 54 is formed on the selected first source/drain region 34 of the first semiconductor structure at the lower portion of first opening 52, and second opening 56 exposes a top surface of first plug 54.

To form second opening 56, a photoresist pattern (not shown) is formed on second insulation interlayer 48a such that a region of a top portion of second insulation interlayer 48a that corresponds to first plug 54 is at least partially exposed through the photoresist pattern. Then, second insulation interlayer 48a, first active thin layer 40, and second plug 55 disposed at the upper portion of first opening 52 are sequentially and partially removed through an etching process using the photoresist pattern as an etching mask until a top surface of first plug 54 is exposed, thereby forming second opening 56 in multilayer insulation pattern 50 that exposes first plug 54. First plug 54 is adapted to function as an etching stop layer so that the etching process by which second opening 56 is formed stops when the top surface of first plug 54 is exposed. The photoresist pattern is completely removed from second insulation interlayer pattern 48 through an ashing process or a stripping process.

Accordingly, multilayer insulation pattern 50 comprising first and second insulation interlayer patterns 38 and 48 is formed on seed layer 30 and second opening 56 in multilayer insulation pattern 50 exposes first plug 54.

First plug 54 functions as an etching stop layer in an etching process through which second opening 56 is formed so that a bottom portion of second opening 56 can be more readily formed at a correct position relative to a conventional device.

Referring to FIG. 3, a metal wiring 58 fills second opening 56 and makes contact with first plug 54. In the illustrated embodiment, metal wiring 58 comprises a barrier wiring continuously formed along a sidewall and a bottom portion of the second opening 56 and a filling wiring that fills the remainder of second opening 56.

In particular, the barrier wiring is continuously formed on a sidewall of second opening 56 and the top surface of first plug 54, which second opening 56 exposes. That is, the barrier wiring is formed along an inner contour of second opening 56. The barrier wiring is formed along the inner contour of second opening 56 through a chemical vapor deposition (CVD) process or a sputtering process. Additionally, the barrier wiring has a multilayer structure comprising a titanium layer and a titanium nitride layer. In the illustrated embodiment, the titanium layer is formed to a thickness of about 30 Å to 80 Å along the inner contour of second opening 56, and the titanium nitride layer is formed to a thickness of about 80 Å to 150 Å on the titanium layer.

A conductive layer such as a metal layer is formed on second insulation interlayer pattern 48 to a sufficient thickness to fill the remainder of second opening 56, and the conductive layer is then partially removed and planarized through a planarization process until a top surface of the second insulation interlayer pattern 48 is exposed. Accordingly, the conductive layer remains only in second opening 56, thereby forming a filling wiring in second opening 56. In the illustrated embodiment, the filling wiring comprises tungsten because of the beneficial characteristics of tungsten for filling second opening 56.

Metal wiring 58 comprising the barrier wiring and the filling wiring makes electrical contact with first plug 54 at the lower portion of first opening 52. The electrical resistance of first plug 54 is not influenced by metal wiring 58 because first plug 54 is doped with first plug impurities.

Accordingly, second opening 56 may be more readily formed relative to a conventional device because first plug 54 is used as an etching stop layer. Additionally, the electrical resistance of a conductive line comprising first plug 54 and metal wiring 58 is markedly reduced relative to a conventional device. Thus, the reliability of the stacked semiconductor device may be improved in accordance with the present invention despite a complicated method for manufacturing a device in accordance with the present invention.

Triple Stacked Semiconductor Device and Manufacturing Method Thereof

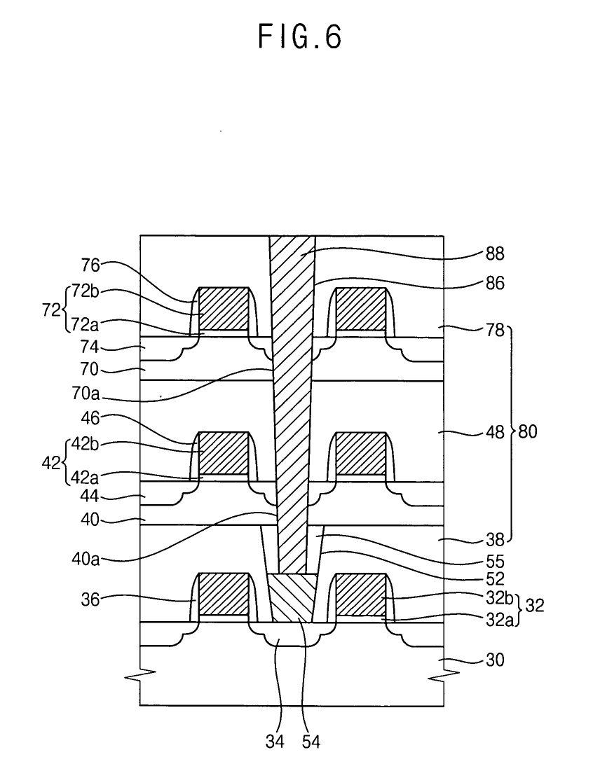

FIG. 6 is a cross-sectional view illustrating a triple-stacked semiconductor device in accordance with an exemplary embodiment of the present invention.

The triple-stacked semiconductor device of FIG. 6 comprises substantially the same structure as the double-stacked-semiconductor device shown in FIG. 3 except that the triple-stacked semiconductor device comprises a third insulation interlayer pattern 78, a second active thin layer 70, and a third semiconductor structure formed on second active thin layer 70, and a multilayer insulation pattern 80 comprising third insulation interlayer pattern 78 and a third opening 86 instead of multilayer insulation pattern 50 comprising second opening 56. Though first, second, and third semiconductor structures of the double-stacked semiconductor device of FIG. 6 each comprise a plurality of transistors, the first, second, and third semiconductor structures will each primarily be described herein with reference to exemplary transistors.

The triple-stacked semiconductor device comprises multilayer insulation pattern 80 comprising first insulation interlayer pattern 38, second insulation interlayer pattern 48 formed on first insulation interlayer pattern 38, and third insulation interlayer pattern 78 formed on second insulation interlayer pattern 48.

First active thin layer 40 is formed on first insulation interlayer pattern 38, and a second active thin layer 70 is formed on second insulation interlayer pattern 48. In the illustrated embodiment, first and second active thin layers 40 and 70 are each formed through a patterning process performed on an epitaxial layer formed through an SEG process.

The second semiconductor structure is formed on first active thin layer 40 and a third semiconductor structure is formed on second active thin layer 70. The third semiconductor structure has substantially the same structure as the first or the second semiconductor structures. In the illustrated embodiment, the third semiconductor structure comprises a third gate pattern 72, which comprises a third gate insulation pattern 72a and a third gate conductive pattern 72b, and third source/drain regions 74. Further, a third spacer 76 is formed on a first sidewall of third gate pattern 72 and a sequential ion implantation process is performed using third gate pattern 72 and third spacer 76 as an ion implantation mask to form lightly-doped junction areas and heavily-doped junction areas in third source/drain regions 74 conventionally known as a lightly-doped source/drain (LDD) structures. Third source/drain regions 74 are doped with third impurities in substantially the same way as first and second source/drain regions 34 and 44 are doped with impurities. Like the first and second semiconductor structures, the third semiconductor structure may further comprise a logic device and/or metal wiring in accordance with a circuit design, as would be known to one of ordinary skill in the art.

Like the first and second semiconductor structures of FIG. 3, when the third semiconductor structure comprises an NMOS transistor, the third impurities comprise at least phosphorous (P) or arsenic (As), and when the third semiconductor structure comprises a PMOS transistor, the third impurities comprise boron (B).

The triple-stacked semiconductor device of the illustrated embodiment comprises a multilayer insulation pattern 80 comprising a third opening 86 penetrating through first, second, and third insulation interlayer patterns 38, 48, and 78, and formed over a selected portion of seed layer 30. In the illustrated embodiment, first plug 54 is formed on seed layer 30 at a lower portion of first opening 52, and third opening 86 exposes a top surface of first plug 54. Third opening 86 also exposes a first sidewall 40a of first active thin layer 40, and a second sidewall 70a of second active thin layer 70. In particular, first sidewall 40a of first active thin layer 40 comprises a sidewall of at least one second source/drain region 44 of the second semiconductor structure, and second sidewall 70a of second active thin layer 70 comprises a sidewall of at least one third source/drain region 74 of the third semiconductor structure.

A metal wiring 88 fills third opening 86 and makes contact with first plug 54. Metal wiring 88 of the illustrated embodiment has substantially the same structure as metal wiring 58 described with reference to FIG. 3, so metal wiring 88 comprises a barrier wiring continuously formed along a sidewall and a bottom portion of third opening 86 and a filling wiring that fills the remainder of third opening 86. The barrier wiring may comprise titanium, titanium nitride, or a combination thereof, and the filling wiring may comprise aluminum, tungsten, copper, or a combination thereof. As an example, the barrier wiring may comprise a multilayer structure comprising a titanium layer and a titanium nitride layer formed on the titanium layer.

Metal wiring 88 in third opening 86 makes electrical contact with first plug 54 at the lower portion of first opening 52. First plug 54 is doped with first plug impurities, so first plug 54 has a relatively low electrical resistance. That is, when first plug 54 makes contact with metal wiring 88, the electrical resistance of a conductive line formed by first plug 54 and metal wiring 88 in first and third openings 52 and 86 may be sufficiently reduced, relative to a conventional device, to improve the reliability of the stacked semiconductor device.

In the illustrated embodiment, first plug 54 doped with first impurities fills a lower portion of first opening 52, and a second plug 55, which is not doped with impurities, fills an upper portion of first opening 52.

That is, first plug 54 doped with the first impurities and second plug 55, which is not doped with impurities, fill first opening 52. Additionally, first active thin layer 40 is not doped with impurities so that the type of transistor (i.e., NMOS or PMOS) that the second semiconductor structure may comprise is not limited. First active thin layer 40 is not doped because, when forming the triple-stacked semiconductor device, an SEG process is performed on second plug 55 and an epitaxial layer is grown from second plug 55. In a subsequent process, the epitaxial layer is formed into first active thin layer 40.

Furthermore, when first and second plugs 54 and 55 fill first opening 52, first plug 54 may be used as an etching stop layer in an etching process through which third opening 86 is formed so that third opening 86 is more readily and accurately formed at a desired position than in the conventional device.

When the triple-stacked semiconductor device is a triple-stacked static random access memory (SRAM) device, a plurality of first NMOS transistors is formed on seed layer 30 as the first semiconductor structure, a plurality of PMOS transistors is formed on first active thin layer 40 as the second semiconductor structure, and a plurality of second NMOS transistors is formed on second active thin layer 70 as the third semiconductor structure. The first semiconductor structure is adapted to function as a pair of pull-down devices and the second semiconductor structure is adapted to function as a pair of pull-up devices. The third semiconductor structure is adapted to function as a pair of access devices. The NMOS transistors, the PMOS transistors, and the second NMOS transistors are electrically connected with one another through first plug 54 and metal wiring 88 to thereby form a triple-stacked SRAM device having a sufficiently reduced electrical resistance relative to a conventional device.

Although a fourth opening and third and fourth plugs in the fourth opening may also be formed in second insulation interlayer pattern 48, the fourth opening and the third and fourth plugs in the fourth opening are removed in the etching process through which third opening 86 is formed, so the resultant structure shown in FIG. 6 does not comprise the fourth opening and the third and fourth plugs in the fourth opening.

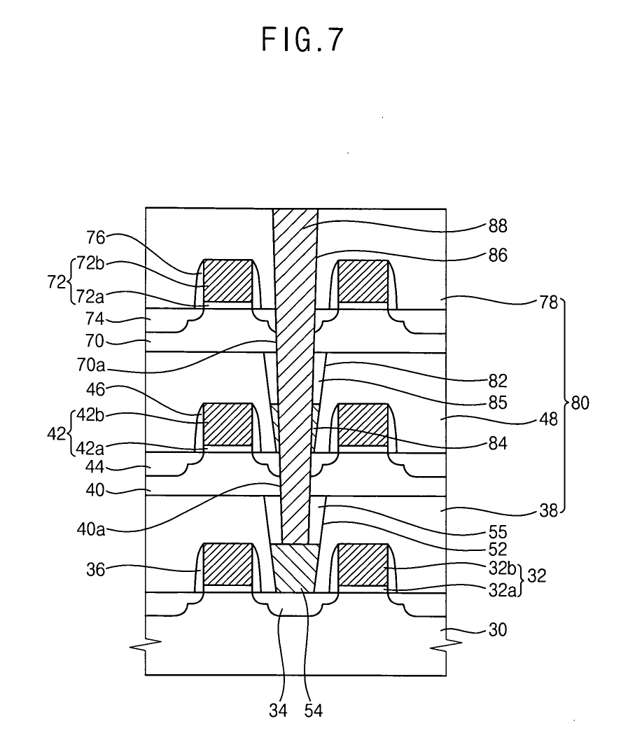

However, in another exemplary embodiment illustrated in FIG. 7, second insulation interlayer pattern 48 comprises a fourth opening 82 that is wider than third opening 86. Also, a third plug 84 doped with second plug impurities and a fourth plug 85, which is not doped with impurities, fill fourth opening 82. The second plug impurities are substantially the same as the second impurities doped into second source/drain regions 44 in the second semiconductor structure. In yet another exemplary embodiment, like alternate first plug 54a in FIG. 4, third plug 84 alone fills third opening 82 (i.e., without fourth plug 85).

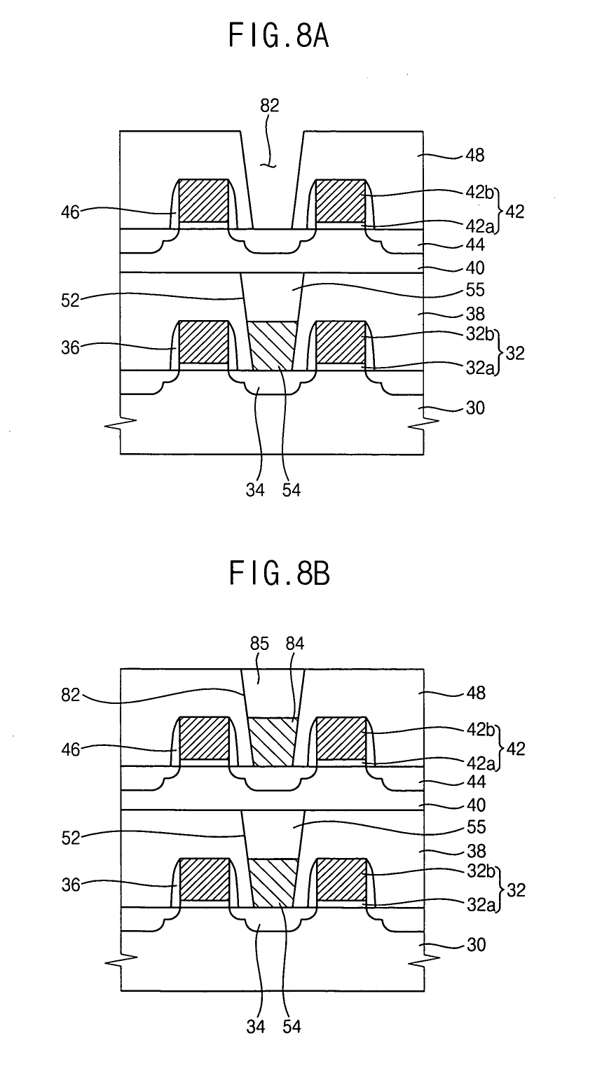

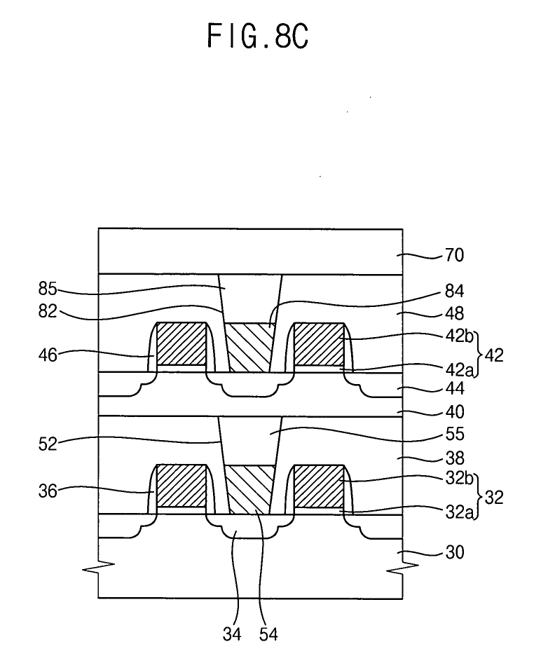

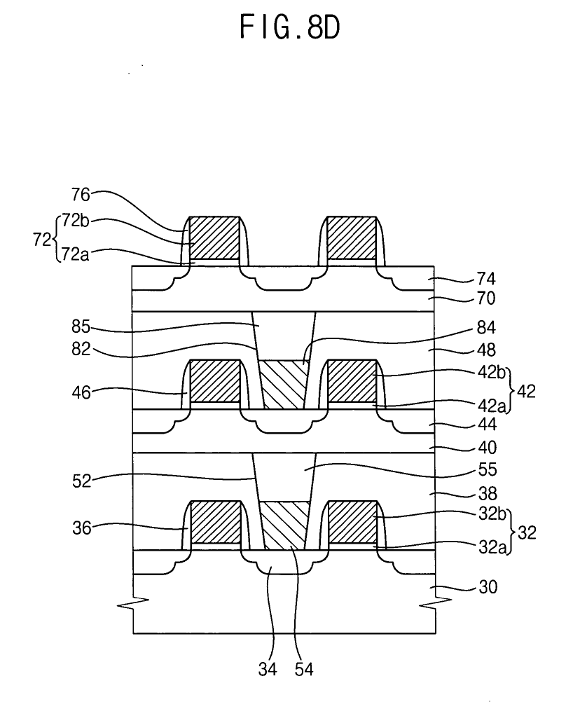

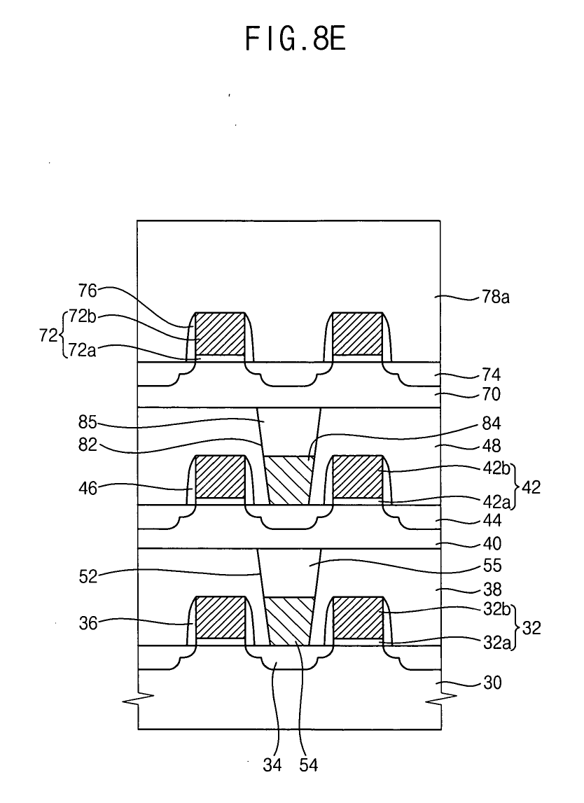

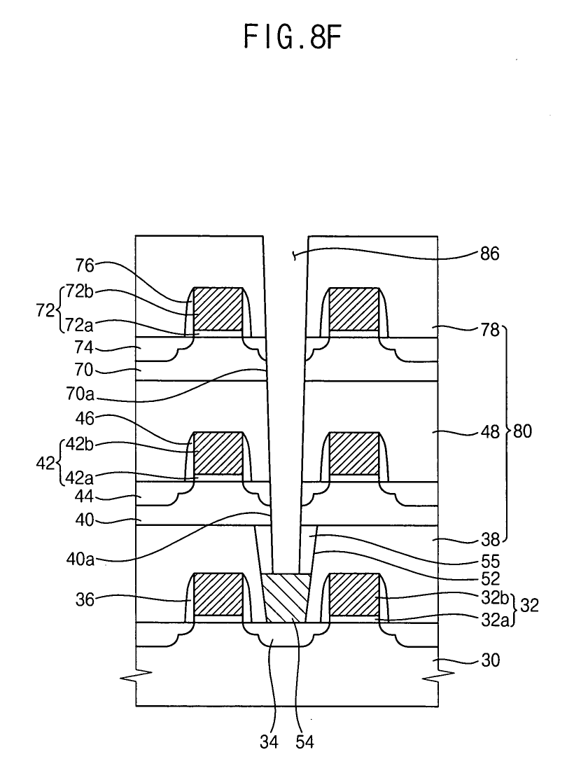

Hereinafter, a method for manufacturing the triple-stacked semiconductor device will be described with reference to FIGS. 8A through 8F. FIGS. 8A through 8F are cross-sectional views illustrating a method for manufacturing the triple-stacked semiconductor device shown in FIG. 6. Though first, second, and third semiconductor structures of the double-stacked semiconductor device of FIGS. 6 and 8 each comprise a plurality of transistors, the first, second, and third semiconductor structures will each primarily be described herein with reference to exemplary transistors.

First, the structure illustrated in FIG. 5H is formed through the process described with reference to FIGS. 5A through 5H, and in particular, second insulation interlayer 48a is formed on first active thin layer 40 on which the second semiconductor structure is formed.

Referring to FIGS. 5H and 8A, second insulation interlayer 48a is partially etched to form second insulation interlayer pattern 48 comprising a fourth opening 82 that exposes a portion of a selected second source/drain region 44 in first active thin layer 40.

To form fourth opening 82, a photoresist pattern (not shown) is formed on second insulation interlayer 48a, and a region of second insulation interlayer 48a corresponding to the selected second source/drain region 44 is at least partially exposed through the photoresist pattern. Then, second insulation interlayer 48a is sequentially and partially removed through an etching process using the photoresist pattern as an etching mask until a portion of a top surface of first active thin layer 40 is exposed, thereby forming second insulation interlayer pattern 48 comprising fourth opening 82 that exposes a portion of the selected second source/drain region 44.

Referring to FIG. 8B, a third plug 84 is formed in third opening 82 and is doped with second plug impurities substantially the same as the second impurities with which second source/drain regions 44 are doped.

Third plug 84 is formed through performing an SEG process and a doping process for doping third plug 84 with second plug impurities. The second plug impurities are substantially the same as the second impurities of second source/drain regions 44 of first active thin layer 40. Like the second impurities the second plug impurities may comprise at least one of phosphorus (P), boron (B), and arsenic (As). For example, when phosphorus (P) is doped into first active thin layer 40 as second impurities, third plug 84 is doped with phosphorus (P) as second plug impurities. Third plug 84 is formed by substantially the same process as the process for forming first plug 54 except that third plug 84 is doped with second plug impurities substantially the same as the second impurities in second source/drain regions 44 rather than first plug impurities in the doping process, so a detailed description of the process for forming third plug 84 is omitted herein.

In the illustrated embodiment, third plug 84 is formed at a lower portion of fourth opening 82, and a fourth plug 85 that is not doped with impurities is formed at an upper portion of third opening 82 through an SEG process. That is, third plug 84 doped with second plug impurities and fourth plug 85, which is not doped with impurities, fill fourth opening 82. The SEG process for forming fourth plug 85 is substantially the same as the process for forming second plug 55, so a detailed description of the SEG process for forming fourth plug 85 is omitted herein.

In addition, when the SEG process continues after fourth plug 85 has been formed and an ELO process is performed on a surface of second insulation interlayer pattern 48, an epitaxial thin layer that may subsequently be used to form a second active thin layer 70 on second insulation interlayer pattern 48.

However, in the illustrated embodiment, the ELO process is not performed in the SEG process for forming fourth plug 85, and fourth plug 85 fills the upper portion of fourth opening 82. That is, third and fourth plugs 84 and 85 completely fill fourth opening 82.

Referring to FIG. 8C, a second active thin layer 70 is formed on second insulation interlayer pattern 48 and fourth plug 85. Second active thin layer 70 is formed as a channel region for a semiconductor structure and has a structure substantially the same as that of first active thin layer 40 and seed layer 30. Second active thin layer 70 is formed by substantially the same process as the process for forming first active thin layer 40, so a detailed description of the process for forming second active thin layer 70 is omitted herein.

Referring to FIG. 8D, a third semiconductor structure comprising a third gate pattern 72 and third source/drain regions 74 is formed on second active thin layer 70. The third semiconductor structure is formed by substantially the same process as the process for forming first or second semiconductor structure.

To form the third semiconductor structure, an insulation layer and a conductive layer are formed on second active thin layer 70 through the same process as that described with reference to FIG. 5A, and the insulation layer and the conductive layer are then patterned through a photolithography process. Accordingly, third gate pattern 72, comprising third gate insulation pattern 72a and third gate conductive pattern 72b, is formed on second active thin layer 70. An ion implantation process is performed at surface portions of second active thin layer 70 using third gate pattern 72 as an implantation mask to thereby form a lightly-doped junction area in a region of second active thin layer 70 adjacent to third gate pattern 72. A third spacer 76 is then formed on a first sidewall of third gate pattern 72, and an ion implantation process is repeated at surface portions of second active thin layer 70 using third gate pattern 72 and third spacer 76 as an ion implantation mask to thereby form a heavily-doped junction area in a region of second active thin layer 70 adjacent to third spacer 76. Accordingly, lightly-doped source/drain (LLD) structures comprising the lightly-doped junction area and the heavily-doped junction area are formed at surface portions of second active thin layer 70 as third source/drain regions 74.

The impurities in third source/drain regions 74 of the third semiconductor structure may be different from the first impurities in first source/drain regions 34 of the first semiconductor structure and the second impurities in second source/drain regions 44 of the second semiconductor structure, so hereinafter the impurities in third source/drain regions 74 will be referred to as third impurities.

Referring to FIG. 8E, a third insulation interlayer 78a is formed on second active thin layer 70, on which the third semiconductor structure is disposed. Third insulation interlayer 78a comprises substantially the same structure as first insulation interlayer 38a and second insulation interlayer 48a, so third insulation interlayer 78a comprises a silicon oxide layer. A borophosphor silicate glass (BPSG) layer, a phosphor silicate glass (PSG) layer, an undoped silicate glass (USG) layer, and a spin on glass (SOG) layer are each exemplary silicon oxide layers.

Referring to FIGS. 8E and 8F, third insulation interlayer 78a is partially etched to form a third insulation interlayer pattern 78 on second active thin layer 70. In addition to third insulation interlayer 78a, second active thin layer 70, third and fourth plugs 84 and 85 disposed in fourth opening 82, first active thin layer 40, and second plug 55 disposed at the upper portion of first opening 52 are continuously and partially etched, except for third and fourth plugs 84 and 85 which are completely etched to form a third opening 86. Third opening 86 penetrates third insulation interlayer pattern 78, second active thin layer 70, second insulation interlayer pattern 48, first active thin layer 40, and second plug 55 disposed in first opening 52 of first insulation interlayer pattern 38. Accordingly, a multilayer insulation pattern 80 comprising first insulation interlayer pattern 38, second insulation interlayer pattern 48, and third insulation interlayer pattern 78 is formed on seed layer 30; and third opening 86 is formed in multilayer insulation pattern 80. In addition, third opening 86 is formed over the selected first source/drain region 34 of the first semiconductor structure. In the illustrated embodiment, first plug 54 is formed on the selected first source/drain region 34 of the first semiconductor structure at the lower portion of first opening 52, and third opening 86 exposes the top surface of first plug 54.

To form third opening 86, a photoresist pattern (not shown) is formed on third insulation interlayer 78a and a region of third insulation interlayer 78a corresponding to first plug 54 is at least partially exposed through the photoresist pattern. Then, third insulation interlayer 78a, second active thin layer 70, third and fourth plugs 84 and 85, second insulation interlayer pattern 48, first active thin layer 40, and second plug 55 disposed at the upper portion of first opening 52 of first insulation interlayer pattern 38 are sequentially and partially (or, as with third and fourth plugs 84 and 85, completely) etched through an etching process, using the photoresist pattern as an etching mask, until a top surface of first plug 54 is exposed, thereby forming third opening 86 through which first plug 54 is exposed in multilayer insulation pattern 80. First plug 54 functions as an etching stop layer, so the etching process for forming third opening 86 stops when the top surface of first plug 54 is exposed. The photoresist pattern is then completely removed from third insulation interlayer pattern 78 through an ashing process or a stripping process.

Accordingly, multilayer insulation pattern 80 comprising first, second, and third insulation interlayer patterns 38, 48, and 78 is formed on seed layer 30, and third opening 86 in multilayer insulation pattern 80 exposes first plug 54.

First plug 54 functions as an etching stop layer in an etching process for forming third opening 86, so third opening 86 is more readily and accurately formed at a desired position relative to a conventional device.

In addition, metal wiring 88, which makes contact with first plug 54, fills third opening 86. In the illustrated embodiment, metal wiring 88 comprises a barrier wiring continuously formed along a sidewall and a bottom portion of third opening 86 and a filling wiring that fills third opening 86.

Metal wiring 88 of the triple-stacked semiconductor device is formed by substantially the same process as the process for forming metal wiring 58 for the double-stacked semiconductor device, so further detailed description of the process for forming metal wiring 88 is omitted herein.

Metal wiring 88 comprising the barrier wiring and the filling wiring makes electrical contact with first plug 54 at the lower portion of first opening 52, and because first plug 54 is doped with first plug impurities, the electrical resistance of first plug 54 is not influenced by metal wiring 88.

Accordingly, third opening 86 may be more readily and accurately formed in multilayer insulation pattern 80 than in a conventional device because first plug 54 is used as an etch stop layer in the etching process. Additionally, the electrical resistance of the conductive line comprising first plug 54 and metal wiring 88 is sufficiently reduced relative to a conventional device. Thus, both a double-stacked and a triple-stacked semiconductor device in accordance with the present invention has the advantages mentioned above.

Thus, in accordance with the present invention, the reliability of a stacked semiconductor device may be improved relative to a conventional device despite having a complicated manufacturing process.

Although exemplary embodiments described above disclose double-stacked and triple-stacked semiconductor devices, a stacked semiconductor device in accordance with the present invention may comprise more than three insulation interlayer patterns stacked on the substrate.

In accordance with the present invention, metal wiring makes contact with a contact plug doped with impurities to electrically connect an upper semiconductor structure and a lower semiconductor structure without the requirement of exposing a surface portion of the substrate.

The contact plug has a relatively low electrical resistance because of the impurities with which the contact plug is doped, and an electrical connection of the upper semiconductor structure and the lower semiconductor structure does not deteriorate electrical stability of semiconductor devices. Further, the contact plug that is doped with impurities is used as an etching stop layer so that an etching process for the metal wiring may be performed without exposing a surface of the substrate.

Although exemplary embodiments of the present invention have been described, it will be understood that the present invention is not limited to the exemplary embodiments. Rather, various changes and modifications can be made to the exemplary embodiments by one skilled in the art while remaining within the scope of the present invention, as defined by the accompanying claims.

What is claimed is:

1. A stacked semiconductor device comprising:
a seed layer doped with first impurities;
a multilayer insulation pattern disposed on the seed layer comprising at least two insulation interlayer patterns stacked on the seed layer and an opening;
at least one active thin layer, wherein each of the at least one active thin layers is disposed on one of the at least two insulation interlayer patterns of the multilayer insulation pattern, and wherein the opening exposes a side surface of each of the at least one active thin layers; and,
a first plug disposed on the seed layer and doped with second impurities substantially the same as the first impurities, wherein the opening exposes at least a portion of a top surface of the first plug.

2. The device of claim 1, wherein the seed layer comprises at least one selected from the group consisting of a silicon substrate, a silicon-on-insulation (SOI) substrate, a germanium substrate, a germanium-on-insulation (GOI) substrate, a silicon-germanium substrate, and an epitaxial layer formed through a selective epitaxial growth (SEG) process.

3. The device of claim 1, wherein the at least one active thin layer comprises an epitaxial layer formed through an SEG process.

4. The device of claim 1, wherein the first and second impurities each comprise at least one of boron (B), phosphorus (P), or arsenic (As).

5. The device of claim 1, further comprising a second plug disposed on the first plug, wherein the second plug is not doped with impurities.

6. A method of manufacturing a stacked semiconductor device comprising:
doping a seed layer with first impurities;
forming a multilayer insulation pattern on the seed layer, wherein the multilayer insulation pattern comprises at least two insulation interlayer patterns vertically stacked on the seed layer and an opening;
forming at least one active thin layer, wherein each of the at least one active thin layers is formed on one of the at least two insulation interlayer patterns of the multilayer insulation pattern, and wherein the opening exposes a side surface of each of the at least one active thin layers; and,
forming a first plug doped with second impurities substantially the same as the first impurities on the seed layer, wherein forming the first plug on the seed layer comprises growing a base layer by performing a first selective epitaxial growth (SEG) process using the seed layer as a seed and doping the base layer with second impurities; and,
forming a metal wiring in the opening, wherein the metal wiring is electrically connected to the first plug.

7. The method of claim 6, wherein the seed layer comprises at least one selected from the group consisting of a silicon substrate, a silicon-on-insulation (SOI) substrate, a germanium substrate, a germanium-on-insulation (GOI) substrate, a silicon-germanium substrate, and an epitaxial layer formed through a second SEG process.

8. The method of claim 6, wherein forming the at least one active thin layer comprises performing a second SEG process.

9. The method of claim 6, wherein doping the base layer with second impurities comprises performing a gas flow process in-situ with the first SEG process.

10. The method of claim 6, wherein doping the base layer with second impurities comprises performing an ion implantation process after growing a base layer through the first SEG process.

11. The method of claim 6, wherein the first and second impurities each comprise at least one of boron (B), phosphorus (P), or arsenic (As).

12. The method of claim 6, further comprising forming a second plug on the first plug, wherein the second plug is not doped with impurities.

13. The method of claim 12, wherein forming the second plug comprises performing a second SEG process.

14. A method of manufacturing a stacked semiconductor device comprising:
forming a first semiconductor structure on a semiconductor substrate, wherein the first semiconductor structure comprises a first gate pattern and first source/drain regions doped with first impurities;
forming a first insulation interlayer on the semiconductor substrate after forming the first semiconductor structure;
patterning the first insulation interlayer to form a first insulation interlayer pattern comprising a first opening, wherein the first opening exposes a portion of the semiconductor substrate comprising at least a portion of a first source/drain region of the first semiconductor structure;
forming a first plug doped with first plug impurities in the first opening and on the portion of the semiconductor substrate exposed by the first opening, wherein forming the first plug comprises forming a base layer through a first selective epitaxial growth (SEG) process using the portion of the semiconductor substrate exposed through the first opening as a seed and doping the base layer with first plug impurities substantially the same as the first impurities;
forming a second plug not doped with impurities on the first plug in the first opening after forming the first plug;
forming a first active thin layer on the first insulation interlayer pattern after forming the second plug;
forming a second semiconductor structure on the first active thin layer, wherein the second semiconductor structure comprises a second gate pattern and second source/drain regions doped with second impurities;
forming a second insulation interlayer on the first active thin layer after forming the second semiconductor structure on the first active thin layer;
forming a second opening, wherein forming the second opening comprises etching the first active thin layer and the second plug using the first plug in the first opening as an etching stop layer, and wherein the second opening exposes a side surface of the first active thin layer comprising a side surface of at least one second source/drain region and a top surface of the first plug; and,
forming a metal wiring in the second opening, wherein the metal wiring is electrically connected to the first plug in the first opening.

15. The method of claim 14, wherein doping the base layer with plug impurities comprises performing a gas flow process in-situ with the first SEG process.

16. The method of claim 14, wherein doping the base layer with plug impurities comprises performing an ion implantation process after the first SEG process.

17. The method of claim 14, wherein the first active thin layer is formed through a second SEG process.

18. The method of claim 14, wherein forming the second opening further comprises etching the second insulation interlayer.

19. The method of claim 14, further comprising:
patterning the second insulation interlayer to form a second insulation interlayer pattern comprising a third opening, wherein the third opening exposes a portion of the first active thin layer comprising at least a portion of a second source/drain region of the second semiconductor structure;
forming a third plug doped with second plug impurities in the second opening and on the portion of the first active layer exposed by the second opening, wherein the second plug impurities are substantially the same as the second impurities; and,
forming a fourth plug not doped with impurities on the third plug in the second opening after forming the third plug,
wherein forming the second opening further comprises etching the third and fourth plugs.

20. The method of claim 14, wherein the first and second impurities each comprise at least one of boron (B), phosphorus (P), or arsenic (As).
